(19) United States
(12) Patent Application Publication
(10) Pub. No.: US 2005/0275835 A1
(43) Pub. Date: Dec. 15, 2005

(54) Method and apparatus for protecting an EUV reticle from particles

(75) Inventor: Michael Sogard, Menlo Park, CA (US)

Correspondence Address: AKA CHAN LLP, 900 LAFAYETE STREET, SUITE 710, SANTA CLARA, CA, 95050, US

(73) Assignee: Nikon Corporation, Tokyo (JP)

(21) Appl. No.: 10/868,428

(22) Filed: Jun. 15, 2004

(51) Int. Cl. G03F 1/00

(52) U.S. Cl. 356/237.2

(57) ABSTRACT

Methods and apparatus for reducing particle contamination on a reticle used in an extreme ultraviolet (EUV) lithography process. According to one aspect of the present invention, an apparatus that protects a surface of an object includes a plate that is positioned in proximity to the surface and protects at least a first portion of the surface. An opening is defined within the plate, and is such that a second portion of the surface is exposed through the opening. The apparatus also includes at least one magnetic component which creates a static magnetic field that is arranged to deflect charged particles away from the opening and the surface of the object.

### BACKGROUND OF THE INVENTION

1. Field of Invention

The present invention relates generally to equipment used in semiconductor processing. More particularly, the present invention relates to a shield which is arranged to cooperate with a magnetic field and exposure radiation to protect a reticle from particle contamination in an extreme ultraviolet lithography system.

2. Description of the Related Art

In photolithography systems, the accuracy with which patterns on a reticle are projected off of or, in the case of extreme ultraviolet (EUV) lithography, reflected off of the reticle onto a wafer surface is critical. When a pattern is distorted, as for example due to particle contamination on a surface of a reticle, a lithography process which utilizes the reticle may be compromised. Hence, the reduction of particle contamination on the surface of a reticle is crucial.

Photolithography systems typically use pellicles to protect reticles from particles. As will be appreciated by those skilled in the art, a pellicle is a thin film on a frame which covers the patterned surface of the reticle to prevent particles from becoming attached to the patterned surface. Pellicles, however, are not used to protect EUV reticles, since thin films generally are not suitable for providing protection in the presence of EUV radiation. Principles of thermophoresis are also often applied to protect reticles from particle contamination by maintaining reticles at a higher temperature than their surroundings, and, therefore, causing the particles to move away from the hotter reticle to the cooler surroundings. Since thermophoresis may not be used in a high vacuum environment, while thermophoresis is effective in protecting reticles from particle contamination in some applications, thermophoresis may not be suitable for use in EUV lithography to protect EUV reticles from particle contamination.

One system used to protect EUV reticles takes advantage of the fact that the relatively high energy of EUV photons will generally ionize particles through a photoelectric effect, thereby causing the particles to be charged up. Once charged, an electric field is applied to effectively deflect the particles from a surface, i.e., a surface of an EUV reticle. The use of an electric field, however, while suitable for deflecting particles from a surface of an EUV reticle, may not be practical in some situations. For example, the need for a power supply to provide the electric field may be problematic. In addition, any stray electric field lines which intersect the reticle surface may actually drive charged particles onto the reticle. The use of an electric field alone typically will not prevent the deposition of particles whose trajectory does not intercept the region of EUV radiation on the reticle, as such particles will generally not become charged.

Therefore, what is desired is a system which allows an EUV reticle to be efficiently and effectively protected from particle contamination. That is, what is needed is a system which enables a reticle such as an EUV reticle to be protected from particle contamination without using a pellicle or an electric field.

### SUMMARY OF THE INVENTION

The present invention relates to a physical particle shield which cooperates with a static magnetic field to reduce particle contamination on a reticle used in an extreme ultraviolet (EUV) lithography process. According to one aspect of the present invention, an apparatus that protects a surface of an object includes a plate that is positioned in proximity to the surface and protects at least a first portion of the surface. An opening is defined within the plate, and is such that a second portion of the surface is exposed through the opening. The apparatus also includes at least one magnetic component which creates a static magnetic field that is arranged to deflect charged particles away from the opening and the surface of the object.

In one embodiment, an extension which is coupled to the plate and is arranged about the opening is included in the apparatus. In such an embodiment, the extension is relatively wedgelike in shape.

A reticle shield effectively masks off much of the surface of a reticle and includes an opening which defines an illumination area that may be illuminated by a beam or beams of EUV radiation. When such a reticle shield is used in conjunction with a magnetic field, e.g., a static magnetic field, the likelihood of particles coming into contact with the surface of the reticle is reduced. Particles which pass through the beams of EUV radiation are typically charged, and subsequently deflected away from the opening in the reticle shield and, hence, the surface of the reticle, by the magnetic field. Hence, the number of particles which may pass through the opening is relatively low. To further decrease the number of particles which may pass through the openings, an extension of the reticle shield may be built up around the opening. When the extension is shaped to conform to the profile of the beams of EUV radiation without touching the beams, fewer potential particle trajectories which may result in a particle reaching the surface of the reticle are possible.

According to another aspect of the present invention, a lithographic system includes an object holder, an illumination source, a shield, and a magnetic arrangement. The object holder supports an object having a front surface that is to be protected from particles, while the illumination source is arranged to supply a beam which is capable of providing the particles with charges. The shield, which is positioned in proximity to the object holder, has an opening defined therethrough through which the beam may pass to substantially illuminate an area of the object that is arranged to be supported by the object holder. Finally, the magnetic arrangement provides a magnetic field to deflect the charged particles away from the opening defined in the shield. The magnetic field and the shield cooperate to substantially protect the object from being contaminated by the charged particles. In one embodiment, the beam is a beam of EUV radiation.

In accordance with still another aspect of the present invention, a method for reducing particle contamination on a surface of an object includes providing a shield with an opening defined therein in proximity to the surface of the object, as well as providing a beam through the opening defined in the shield. The beam substantially illuminates an area of the surface, and also generally charges particles which pass through the beam. The method also includes creating a first magnetic field that is arranged to substantially encompass the opening and a portion of the beam near the shield, and deflecting the charged particles away from the opening using the first magnetic field.

In one embodiment, the method further includes creating a second magnetic field. The second magnetic field also substantially encompasses the opening. The second magnetic field has magnetic field lines oriented along a different axis than magnetic field lines of the first magnetic field.

These and other advantages of the present invention will become apparent upon reading the following detailed descriptions and studying the various figures of the drawings.

### BRIEF DESCRIPTION OF THE DRAWINGS

The invention may best be understood by reference to the following description taken in conjunction with the accompanying drawings in which:

FIG. 1a is a diagrammatic side-view representation of a reticle and a reticle shield in accordance with an embodiment of the present invention.

FIG. 1b is a diagrammatic cross-sectional representation of a magnetic field region and an extreme ultraviolet (EUV) radiation region relative to a reticle and a reticle shield, i.e., reticle 100 and shield 104 of FIG. 1a, in accordance with an embodiment of the present invention.

FIG. 1c is a diagrammatic representation of a flux of particles passing through a magnetic field region, i.e., magnetic field region 116 of FIG. 1b, in accordance with an embodiment of the present invention.

FIG. 2a is a diagrammatic cross-sectional side-view representation of a reticle and a reticle shield which includes an extension in accordance with an embodiment of the present invention.

FIG. 2b is a diagrammatic cross-sectional side-view representation of a magnetic field region and an extreme ultraviolet (EUV) radiation region relative to a reticle and a reticle shield which includes an extension, i.e., reticle 200 and shield 204 of FIG. 2a , in accordance with an embodiment of the present invention.

FIG. 2c is a diagrammatic representation of a flux of particles passing through a magnetic field region, i.e., magnetic field region 216 of FIG. 2b, in accordance with an embodiment of the present invention.

FIG. 2d is a diagrammatic top-view representation of a reticle shield which includes an extension, i.e., shield 204 of FIG. 2a, in accordance with an embodiment of the present invention.

FIG. 2e is a diagrammatic side-view representation of a reticle shield which includes an extension, e.g., shield 204 of FIG. 2a, in which a particle may reach the surface of a reticle.

FIG. 2f is a diagrammatic side-view representation of a reticle shield with an extension which may further prevent particles from reaching the surface of a reticle in accordance with an embodiment of the present invention.

FIGS. 3a and 3b are diagrammatic cross-sectional side-view representations of a reticle shield with a wedgelike extension, a particle with a radius of curvature R, and a magnetic field extending a distance h below the reticle shield in accordance with an embodiment of the present invention.

FIG. 4a is a diagrammatic cross-sectional side-view representation of a reticle shield and a reticle in a magnetic field generated by magnetic pole pieces in a first orientation in accordance with an embodiment of the present invention.

FIG. 4b is a diagrammatic top-down representation of a reticle shield and a reticle, i.e., reticle shield 404 and reticle 400 of FIG. 4a, in accordance with an embodiment of the present invention.

FIG. 4c is a diagrammatic cross-sectional side-view representation of a reticle shield and a reticle in a magnetic field generated by magnetic pole pieces in a second orientation in accordance with an embodiment of the present invention.

FIG. 4d is a diagrammatic top-down representation of a reticle shield and a reticle, i.e., reticle shield 474 of FIG. 4c, in a second orientation in accordance with an embodiment of the present invention.

FIG. 5a is a representative diagrammatic cross-sectional side-view representation of a reticle shield and a reticle in a magnetic field generated by magnetic pole pieces in a second orientation in accordance with an embodiment of the present invention.

FIG. 5b is a diagrammatic top-down representation of a reticle shield and a reticle, i.e., reticle shield 504 and reticle 500 of FIG. 5a, in accordance with an embodiment of the present invention.

FIG. 6a is a diagrammatic cross-sectional side-view representation of a reticle shield and a reticle in magnetic fields generated by magnetic pole pieces and a coil in accordance with an embodiment of the present invention.

FIG. 6b is a diagrammatic top-down representation of a reticle shield and a reticle, i.e., reticle shield 604 and reticle 600 of FIG. 6a, in accordance with an embodiment of the present invention.

FIG. 7a is a diagrammatic cross-sectional side view representation of a first cover for an opening in a reticle shield in accordance with an embodiment of the present invention.

FIG. 7b is a diagrammatic cross-sectional side view representation of a second cover for an opening in a reticle shield in accordance with an embodiment of the present invention.

FIG. 7c is a diagrammatic cross-sectional side view representation of a third cover that covers an opening in a reticle shield in accordance with an embodiment of the present invention.

FIG. 8 is a diagrammatic cross-sectional side view representation of a blind arrangement that allows the effective size of an opening in a reticle shield to be adjusted in accordance with an embodiment of the present invention.

FIG. 9 is a block diagram side-view representation of an EUV lithography system in accordance with an embodiment of the present invention.

FIG. 10 is a process flow diagram which illustrates the steps associated with fabricating a semiconductor device in accordance with an embodiment of the present invention.

FIG. 11 is a process flow diagram which illustrates the steps associated with processing a wafer, i.e., step 1304 of FIG. 10, in accordance with an embodiment of the present invention.

### DETAILED DESCRIPTION OF THE EMBODIMENTS

Particle contamination on critical surfaces of reticles such as reticles used in extreme ultraviolet (EUV) lithography systems may compromise the integrity of semiconductors created using the reticles. Hence, protecting critical surfaces of reticles from contaminants is important to ensure the integrity of lithography processes. Some reticles are protected from particles through the use of pellicles. However, pellicles are not suitable for use in protecting surfaces of EUV reticles. While thermophoresis is also often effective in protecting reticle surfaces from particle contamination, since the use of thermophoresis as a method of protection from particle contamination is not suitable in a relatively high vacuum, EUV reticles may not be protected from particle contamination through the use of thermophoresis.

By protecting substantially all of a front surface of a reticle, with the exception of the area of the reticle that is to be illuminated using EUV beams, using a particle shield, particles may be prevented from coming into contact with most of the front surface of the reticle. A shield may include an opening through which EUV beams may pass, and come into contact with a surface of a reticle that is to be illuminated. In order to reduce the number of particles that may pass through such an opening and, hence, become attached to the reticle, a static magnetic field may be applied in the vicinity to cause many particles that may otherwise pass through the opening to be deflected away from the opening. Some shields may include an extension, as for example a substantially wedgelike extension, which further cooperates with the static magnetic field to further reduce the number of particles which may pass through the opening.

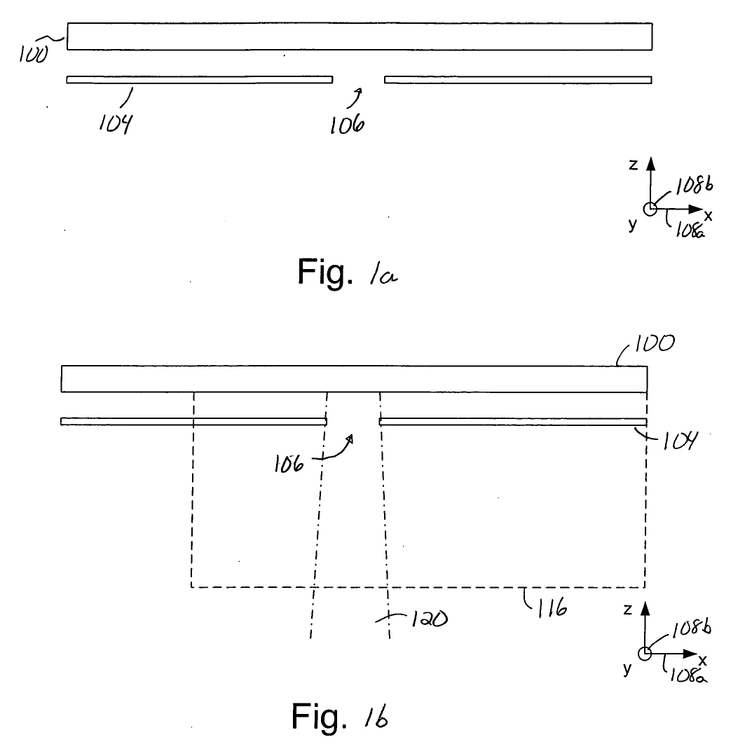

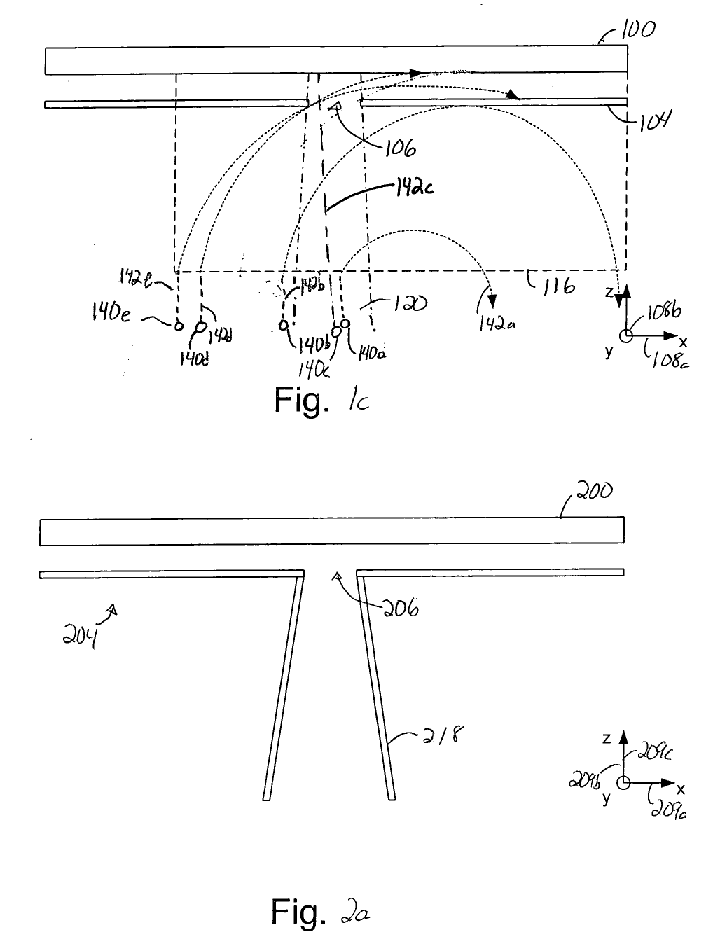

FIG. 1a is a diagrammatic side-view representation of a reticle and a reticle shield in accordance with an embodiment of the present invention. A reticle 100, which may be an EUV reticle, may be mounted on a reticle chuck (not shown) such that a reticle shield 104 is positioned at an offset from a patterned surface of reticle 100. Reticle shield 104 is arranged at least in part to provide a physical barrier to prevent some particles from becoming attached to a front, or patterned, surface of reticle 100. In one embodiment, reticle shield 104 is relatively planar, and is substantially a plate.

Reticle shield 104 has an opening 106 defined therethrough which is arranged to enable EUV radiation to reach the patterned surface of reticle 100. In other words, in order to enable reticle shield 104 to protect reticle 100 while still allowing EUV rays, or radiation, to be reflected off of reticle 100, opening 106 is included in reticle shield 104. Since reticle 100 is arranged to scan, as for example along an x-axis 108a, relative to reticle shield 104, different portions of the patterned surface of reticle 100 may be exposed to EUV radiation through opening 106 as appropriate, while remaining portions of the patterned surface of reticle 100 may be shielded by reticle shield 104 until such time as it is appropriate to expose those portions to EUV radiation.

Opening 106 may have a curvature relative to x-axis 108a and a curvature relative to y-axis 108b. That is, opening 106 may effectively be a curved slit, through which portions of reticle 100 may be illuminated by EUV radiation. The shape of opening 106 may be chosen to conform to a profile of beams of EUV radiation.

Reticle shield 104 may be formed from substantially any suitable material. Typically, reticle shield 104 may have a relatively low magnetic permeability such that reticle shield 104 does not significantly perturb a magnetic field, and may be formed such that surfaces of reticle shield 104 are conductive and grounded. By way of example, reticle shield 104 may be formed from a metal or as an insulator that is covered with a conductive coating of aluminum, copper, or stainless steel. Alternatively, in some embodiments, reticle shield 104 may be made of a material with a high magnetic permeability, both to shape the magnetic field and to shield magnetically sensitive parts of a reticle stage which utilizes reticle shield 104.

While reticle shield 104 is generally effective in reducing particle contamination of reticle 100, some particles may pass through opening 106 and become attached to a patterned surface of reticle 100. To reduce the number of particles which may pass through opening 106, a magnetic field may be positioned in the vicinity of reticle 100 to deflect charged particles. As will be appreciated by those skilled in the art, EUV photons generally have relatively high energy, and will ionize particles through a photoelectric effect, thereby causing the particles to charge up. Substantially any particle that is exposed to an EUV beam for a fraction of a second becomes highly charged. Such charged particles may be deflected using a magnetic field. A magnetic field region 116, as shown in FIG. 1b, is arranged such that opening 106 may be positioned within magnetic field region 116 during an EUV lithography process. EUV radiation 120 effectively has a wedgelike profile due to incident and reflective EUV rays, as will be appreciated by those skilled in the art.

In general, any charged particles which encounter magnetic field region 116 will follow a curved path. EUV photons, which typically comprise the EUV radiation 120, charge particles and therefore cause the particles to follow curved paths through magnetic field region 116. EUV radiation 120 typically causes photoelectron emission from the surfaces of particles, thereby charging the particles to positive voltages. Photoelectrons generated within a few nanometers of the surface of a particle may also be emitted, thereby contributing to the charging of the particle. A particle voltage, as will be appreciated by those skilled in the art, will often eventually become sufficiently positive that a charge state, as defined by Gauss' law, will stabilize, i.e., when photoelectron emission is such that photoelectrons may no longer escape from the attractive electric field surrounding a particle.

The fraction of EUV radiation 120 incident on a substantially spherical particle and absorbed by the particle, as for example any of particles 140 of FIG. 1c, may be given as follows:

$$F ( r ) = 1 - 2 {\int }_{0}^{π / 2} exp [ \frac{- 2 r cos θ}{λ} ] cos θ sin θ ⅆ θ$$

where F(r) is the fraction of EUV radiation absorbed by a particle, r is a radius of a particle and λ is a photoabsorption attenuation length. Using the above relationship, it has been observed that smallest particles generally travel the farthest before their charge state stabilizes, but they are also deflected the most.

If a relatively significant charge is induced and particles have a relatively low momentum, magnetic field region 116 may be effective in deflecting particles away from opening 106 and, hence, reticle 100. FIG. 1c shows particles passing through magnetic field region 116. It should be appreciated that magnetic field lines within magnetic field region 106 are approximately parallel to reticle 100 or, more specifically, are approximately parallel to y-axis 108b. Particles 140 follow curved paths 142. If magnetic field region 116 is a uniform magnetic field B, and particles 140 each have a charge Q and a velocity v, then each particle 140 may follow a substantially helical path or trajectory 142 of a radius R which may be expressed as:

$$R = \frac{mv}{QB}$$

where m is the mass of a particle 140. Since particles 140 are often spherical, assuming a particle of radius r and a density ρ, the particle mass m may be expressed as:

$$m = \frac{4}{3} π {r}^{{3}^{5}} ρ$$

Hence, the radius R for each trajectory 142 associated with a particle 140 is given by:

$$R = \frac{4 π {r}^{3} ρ v}{3 QB}$$

It should be understood that the above relationships between the magnetic field, the radius R, and the particle properties are based on the assumption that the magnetic field may be approximately uniform within a finite region of space. In an embodiment in which the magnetic field is not approximately uniform, the above relationships may be more complicated.

If radius R of a trajectory 142 of a particle 140, which generally increases with particle momentum and also with decreasing charge, is less than a certain amount, then the particle 140 is not likely to reach reticle 100 even without reticle shield 104 in place. In one embodiment, when radius R of a trajectory 142 of a particle 140 is less than the extent of magnetic field 116, then particle 140 generally will not reach reticle 100. It should be understood that although increasing the magnitude of magnetic field B generally serves to reduce the radius R of a trajectory 142 of a particle 140 even as the particle momentum increases, there are typically limits to the magnitude of magnetic field B.

As shown in FIGS. 1b and 1c, as well as in subsequent figures, the extent of a magnetic field region such as magnetic field region 116 is represented by a relatively sharp boundary for ease of illustration. As will be appreciated by those skilled in the art, a magnetic field typically decreases from a relatively large value to a relatively small value over a finite distance. Within such a distance particles are deflected by a relatively small amount. However, such a decrease in the value associated with the magnetic field has not been shown in the figures.

Reticle shield 104 protects reticle 100 from particles 140 except where opening 106 is located. Even with a significant number of particles 140 being deflected away from opening 106, and other particles 140 being prevented from reaching reticle 100 by the physical presence of reticle shield 104, some particles, as for example particles 140c, 140d on paths 142c, 142d, respectively, may pass through opening 106 and become attached to a front surface of reticle 100. Typically, particles such as particles 140c, 140d which may become attached to a front surface of reticle 100, are particles which are uncharged or weakly charged. A particle may be uncharged or weakly charged when the particles do not have a significant exposure to EUV radiation 120, i.e., are not within an EUV beam envelope. It should be appreciated that even if some particles are not exposed to EUV radiation 120, those particles may be charged in the event that such particles were previously exposed to an EUV beam or other ionizing beam such as an electron beam.

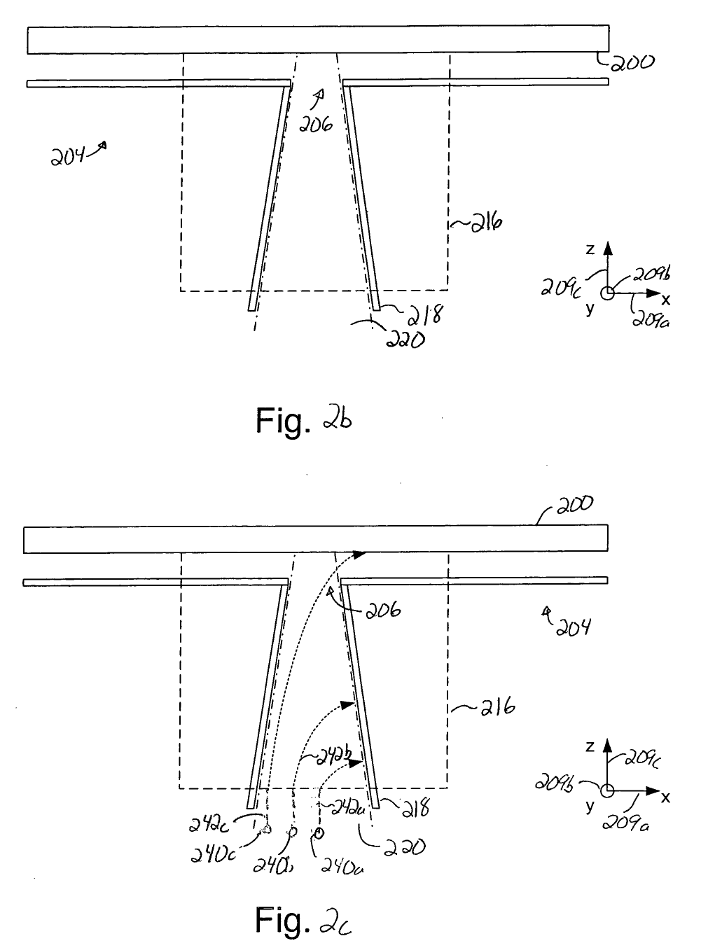

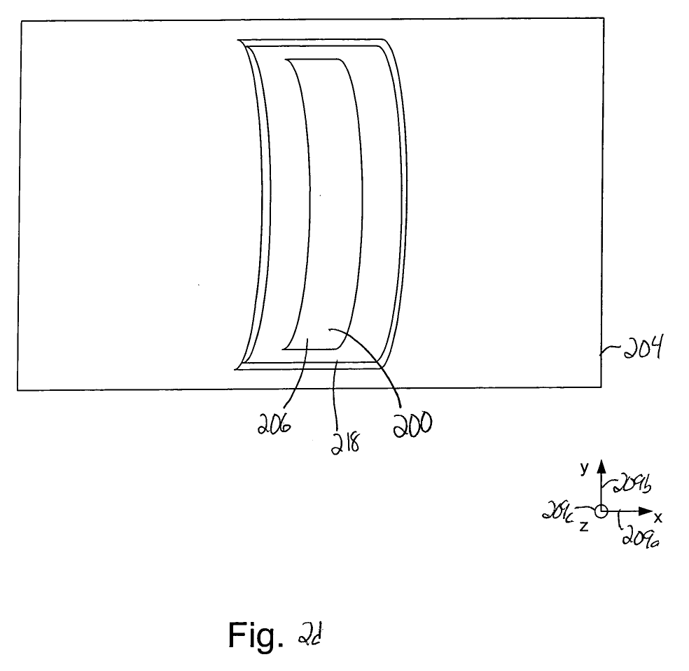

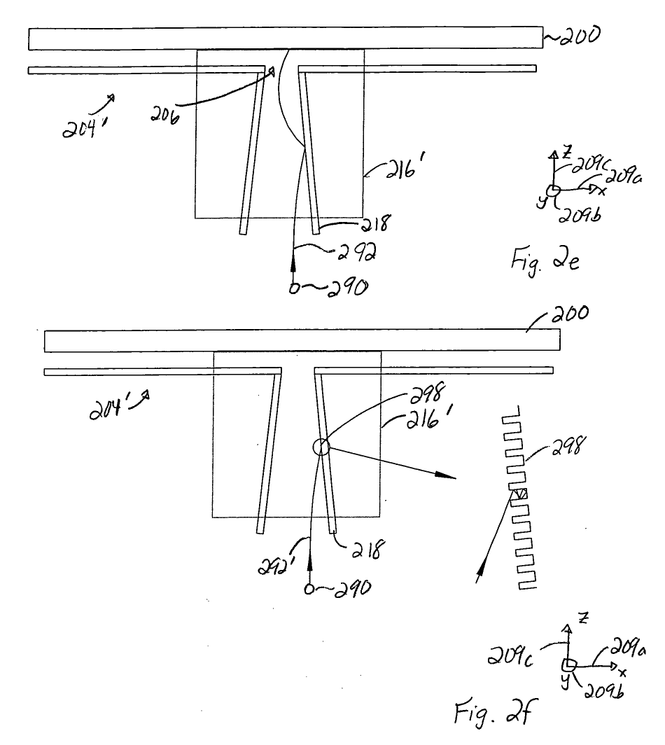

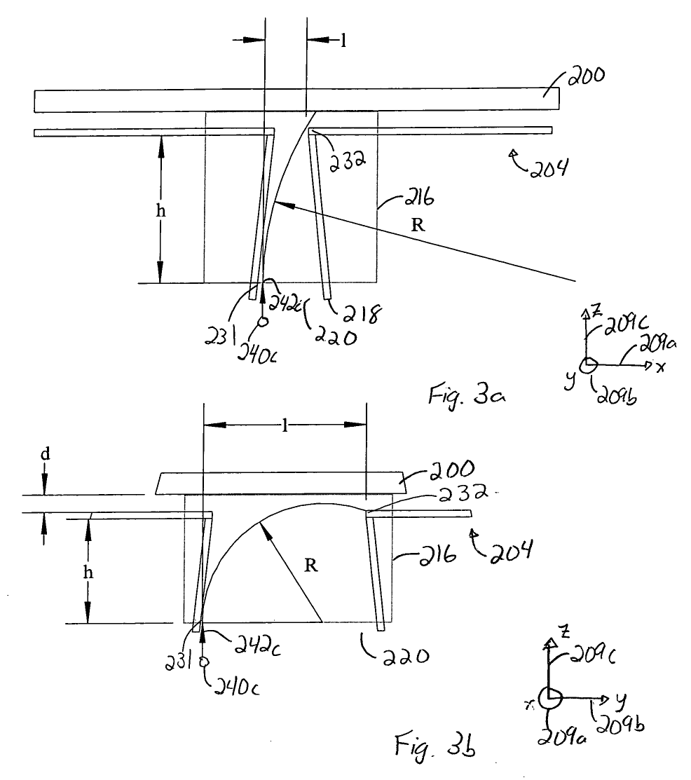

While reticle shield 104 is effective in reducing a number of particles 140 which may cause particle contamination on reticle 100, reticle shield 104 may be configured to reduce the likelihood that uncharged or weakly charged particles 140 pass through opening 106 and attach to reticle 100. In one embodiment, an extension may be added to a reticle shield to block some uncharged or weakly charged particles from passing through an opening in the reticle shield. FIG. 2a is a diagrammatic cross-sectional side-view representation of a reticle and a reticle shield which includes an extension in accordance with an embodiment of the present invention. A reticle shield 204 includes a plate in an xy-plane, and an extension 218 which, as shown in FIG. 2d, has curved sides. The outline of the sides of extension 218 is curved to accommodate the profile of an EUV beam envelope or EUV radiation (not shown) about which extension 218 is arranged, as will be described below.

Reticle shield 204 is often formed from materials which are characterized by a relatively low magnetic permeability, so as not to perturb a magnetic field (not shown) which is used in conjunction with reticle shield 204. However, it should be appreciated that substantially any suitable material may generally be used to form reticle shield 204. An opening 206, which has substantially the same shape as extension 218 with respect to x-axis 209a and y-axis 209b, is effectively flanked by extension 218. Extension 218 is arranged to restrict the range of particle trajectories that may pass through opening 206. In other words, extension 218 is arranged to prevent some particles from passing through opening 206 by providing a physical barrier to those particles. FIG. 2b shows reticle 200 and reticle shield 204 in a magnetic field 216, i.e., a static magnetic field, in accordance with an embodiment of the present invention. An EUV beam envelope or EUV radiation 220 is arranged such that extension 218 does not come into contact with the edges of EUV radiation 220. Typically, extension 218 is arranged to be as close to EUV radiation 220 as possible, without coming into contact with EUV radiation 220. As shown, extension 218 may be of an approximately hollow wedgelike shape and is arranged about EUV radiation 220 such that EUV radiation 220 does not contact the inner sides of extension 218.

Extension 218 is generally positioned such that extension 218, as well as opening 206, are within magnetic field 216. Magnetic field 216 causes highly charged particles, as for example particles which are intercepted by EUV radiation 220 and are in the vicinity of reticle 200 and reticle shield 204, to move on trajectories which divert the particles away from opening 206. Many particles which are either uncharged or weakly charged, such as particles which are not intercepted by EUV radiation 220, are typically blocked from entering opening 206 by extension 218.

As shown in FIG. 2c, while most particles 240a, 240b which are exposed to EUV radiation 220 move on trajectories 242a, 242b, respectively, which prevent particles 240a, 240b from becoming attached to reticle 200, a certain types of particles such as particle 240c may pass through opening 206 and contaminate reticle 200. When particle 240c has either or both a relatively high particle momentum or a relatively small electric charge, trajectory 242c may be such that particle 240c passes through opening 206 and comes into contact with a front surface of reticle 200, as magnetic field 216 may not be sufficient to alter trajectory 242c enough to prevent particle 240c from passing through opening 206.

In general, for a given amount of charge on a particle, a reticle may not have to be protected from particles with an arbitrarily large amount of momentum. It is known that particles incident approximately normally on a surface will bounce off of the surface rather than stick to the surface, if their velocities exceeds a critical amount. For example, results from B. Dahneke in the Journal of Colloid and Interface Science, Vol. 37, 342(1971), which is incorporated herein by reference in its entirety, indicate that silica particles bounce off a quartz surface, if the component of normally incident velocity exceeds several milliseconds, for particle sizes greater than approximately thirty nanometers. These conditions are, in one embodiment, substantially representative of those for a EUV reticle. Therefore, provided extension 218 blocks uncharged or weakly charged particles from opening 206, and magnetic field 216 is sufficiently strong so as to deflect particles with velocities approximately equal to the critical velocity away from opening 206, reticle 200 may be protected from particles with an arbitrary velocity spectrum.

In one embodiment, in order to further reduce the number of particles which may be prevented from reaching reticle 200, a mechanism exists as will be described with respect to FIGS. 2e and 2f, which may be implemented as a part of a reticle shield 204′. A particle 290 with a trajectory 292 enters a magnetic field region 216′ with a velocity exceeding a critical velocity. Particle 290 may strike extension 218, bounce off, and strike the reticle 200. The collision of particle 290 with extension 218 is typically inelastic, and may reduce the velocity of particle 290 to below the critical value. Hence, when particle 290 subsequently strikes reticle 200, particle 290 sticks to reticle 200.

FIG. 2f shows reticle shield 204′ with a mechanism which is arranged to further reduce the likelihood of particle 290 sticking to reticle 200 in accordance with an embodiment of the present invention. An interior surface 298 of extension 218 is roughened, or covered with baffles, so that particle 290 colliding with interior surface 298 may essentially lose all its energy and stick to interior surface 298. Alternatively, particle 290 may escape from interior surface 298 with so little energy that magnetic field 216′ is successful in preventing particle 290 from hitting reticle 200.

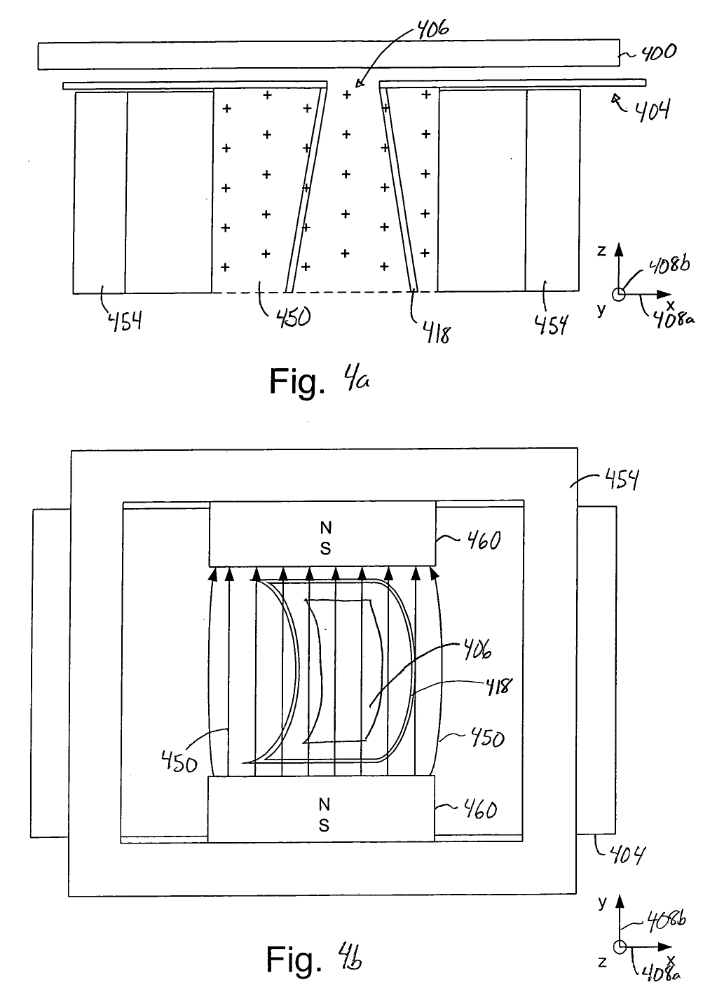

The maximum radius of curvature Rₘₐₓ that a trajectory such as trajectory 242c of particle 240c of FIG. 2c may have within magnetic field 216 or, more specifically, within the space bounded by extension 218, while preventing particle 240c from coming into contact with a front surface of reticle 200 may be determined using geometrical relationships. With reference to FIG. 3a, the calculation of a maximum radius of curvature Rₘₐₓ for a trajectory which a particle 240 within the boundaries of extension 218 may follow without coming into contact with a front surface of reticle 200 will be described in accordance with an embodiment of the present invention. The maximum radius of curvature describes the path of a particle which enters magnetic field region 216 in z-direction 209c, passes very close to a left side surface 231 of extension 218, and hits a right side surface 232 of reticle shield 204. The separation between these two points, along x-direction 209a is given by l. Rₘₐₓ may then be given by

$${R}_{max} = \frac{{l}^{2} + {h}^{2}}{2 l} ,$$

where h is the distance measured along z-direction 209c over which magnetic field 216 exerts a force on particle 240c. As described, an assumption that h≧l has been made. If such a condition is violated, particle 240c will generally pass closer to reticle 200 than the surface of reticle shield 204 which faces reticle 200, as shown in FIG. 3b, and may strike reticle 200 before reaching a right side edge of reticle shield 204. If the spacing between reticle 200 and the facing surface of reticle shield 204 is denoted by a distance d, it may be shown that particle 240c will miss reticle 200 provided that
Rₘₐₓ<h+d
and
h>l−[2ld]^{1/2}.

When length l is much smaller than height h, the maximum radius of curvature Rₘₐₓ for a trajectory of a particle, if the particle is not to come into contact with reticle 200, may be approximated as:

$${R}_{max} \approx \frac{{h}^{2}}{2 l}$$

Solving for height h as a function of the maximum radius of curvature Rₘₐₓ yields:
h≈\sqrt{2lRₘₐₓ}
When length l and the maximum radius of curvature Rₘₐₓ are known, height h may be estimated.

As shown, the radius of curvature R of trajectory 242c exceeds the maximum radius of curvature Rₘₐₓ. Hence, particle 240c comes into contact with reticle 200. If particle 240c is not to come into contact with reticle 200, and particle 240c has a relatively low charge and a relatively high momentum, then magnetic field 216 may be altered such that height h and, hence, the maximum radius of curvature Rₘₐₓ are larger. It should be appreciated, however, that it may not always be possible to increase height h and the maximum radius of curvature Rₘₐₓ due, for example, to physical constraints.

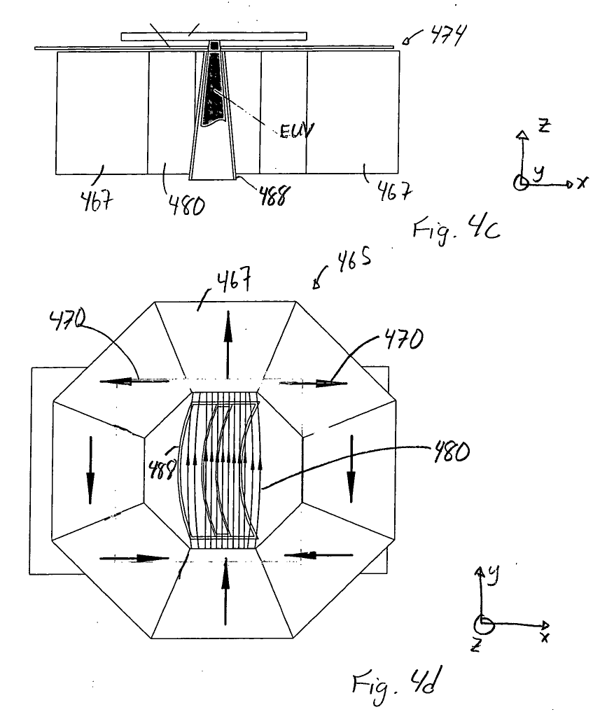

The height of a static magnetic field such as magnetic field 216 is generally dependent upon the size of magnetic pole pieces used to generate the magnetic field. In one embodiment, magnetic pole pieces are permanent magnets, although it should be appreciated that the magnetic pole pieces may instead be electromagnets. With reference to FIGS. 4a and 4b, the use of permanent magnets to create a magnetic field within which a reticle shield with an extension may be used will be described in accordance with an embodiment of the present invention. FIG. 4a is a representative diagrammatic cross-sectional side-view representation of a reticle shield and a reticle, while FIG. 4b is a diagrammatic top-down representation of the reticle shield and magnetic poles. A reticle shield 404, which includes an extension 418, is positioned such that a reticle 400 which is protected from particle contamination by reticle shield 404 may scan relative to reticle shield 404 along an x-axis 408a. Permanent magnets 460 are positioned about extension 418 such that an opening 406 in reticle shield 404 falls within the scope of magnetic field 450, which has field lines along a y-axis 408b. A yoke 454, e.g., an iron yoke, is coupled to magnets 460 to allow for flux circulation.

The spacing of magnets 460 is relatively far apart, with respect to y-axis 408b, and is such that the maximum deflection required for particles to be deflected away from passing through opening 406 is relatively small. However, due to magnets 460 being separated by a relatively large gap, the strength of magnetic field 450 may be somewhat limited. That is, since magnets 460 are spaced apart by a gap that is larger than a length of opening 406 along y-axis 208b, the strength of magnetic field 450 may not be high enough for some systems.

With reference to FIGS. 4c and 4d, another embodiment of a permanent magnet configuration which provides a greater magnetic field in a y-direction will be described in accordance with an embodiment of the present invention. An array 465 of permanent magnets 467 is arranged in a closed circuit. A direction of magnetization 470 in each permanent magnet may be adjusted such that each magnet 467 contributes to a magnetic field 480 within an extension 488 of a reticle shield 474. Such an embodiment may substantially minimize stray magnetic fields in the vicinity of array 465. Such arrays of permanent magnets are described by K. Halbach in Journal of Applied Physics, Vol. 57, 3605(1985), which is incorporated herein by reference in its entirety.

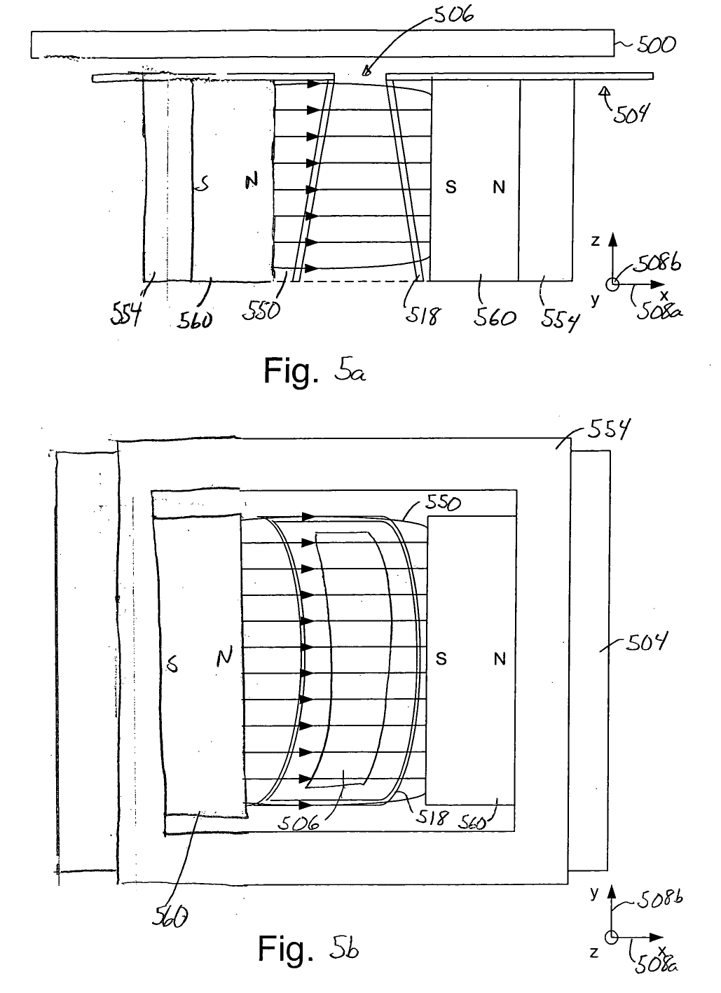

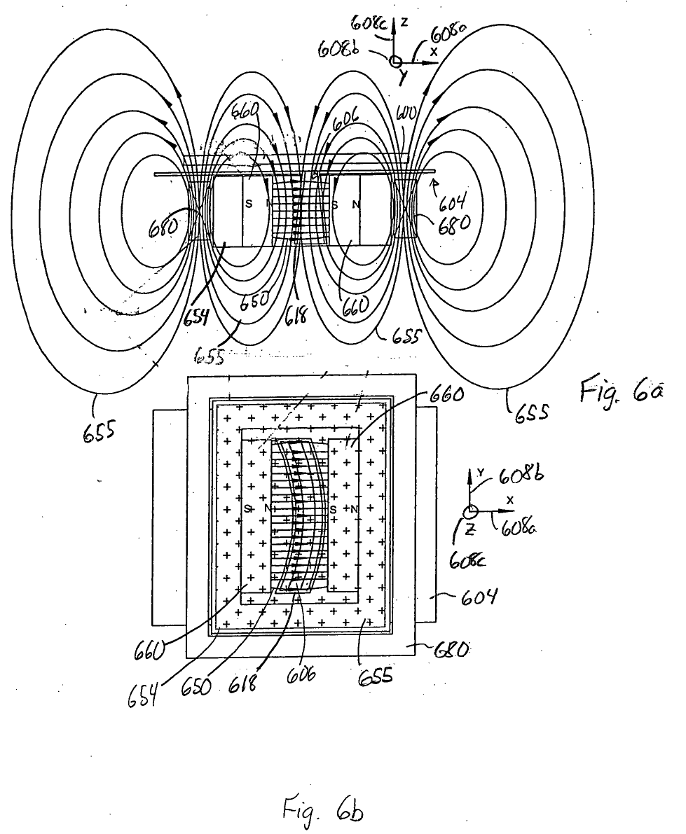

In order to increase the maximum magnetic field used to deflect particles away from a surface of a reticle, the size of the gap between magnets used to generate the magnetic field may be decreased. To decrease the size of the gap or space between the magnets, the magnets may be oriented as shown in FIGS. 5a and 5b. FIG. 5a is a representative diagrammatic cross-sectional side-view representation of a reticle shield and a reticle, while FIG. 5b is a diagrammatic top-down representation of the reticle shield and magnetic poles in a second orientation in accordance with an embodiment of the present invention. A reticle shield 504 includes an extension 518, and has an opening 506 defined therein. Reticle 500 is protected from particle contamination by reticle shield 504, and scans relative to reticle shield 504 along an x-axis 508a.

A magnetic field 550 is generated with field lines which run in a direction along x-axis 508a, and serves to deflect particles with respect to a yz-plane. Permanent magnets 560, or magnetic pole pieces, are positioned about extension 518 such that opening 506 falls within the region of magnetic field 550, and a gap between magnets 560 is defined along x-axis 508a. A magnetic flux circuit return or yoke 554, which may be formed from iron, is coupled to magnets 560.

The positioning of magnets 560 enables the separation between magnets 560 to be smaller than the positioning of magnets 460 of FIGS. 4a and 4b allows, and also allows for the strength of magnetic field 550 to be increased. Magnets 560 may be positioned closer together by shaping the faces of magnets 560 adjacent to extension 518 to match the shape of the surfaces of extension 518. However, the decrease in the size of the gap between magnets 560, and the increase in the strength of magnetic field 550, may be accompanied by an increase in the maximum particle deflection required within extension 518 to deflect particles away from opening 506.

To decrease the maximum particle deflection requirement within extension 518, while still allowing the spacing between magnets 560 to remain substantially the same, a further magnetic field may effectively be added to magnetic field 550, as for example by a coil or by permanent magnets. With reference to FIGS. 6a and 6b, a system which uses a reticle shield that includes an extension in conjunction with magnetic fields in more than one direction will be described in accordance with an embodiment of the present invention. A reticle shield 604, which includes an extension 618 and defines an opening 606, is arranged to cooperate with a first magnetic field 650 and a second magnetic field 655 to minimize the number of particles which may come into contact with reticle 600. First magnetic field 650 is created by pole pieces or magnets 660, and includes magnetic field lines which run along an x-axis 608a, and is substantially the same as magnetic field 550 of FIGS. 5a and 5b. Second magnetic field 655 is created by or imposed by coil 680, in the described embodiment, and include magnetic field lines that are approximately normal to a front surface of reticle 600. That is, the magnetic field lines of second magnetic field 655 run approximately in a direction along a z-axis 608c in the vicinity of reticle 600. Coil 680 is positioned substantially surround a yoke 654, or a magnetic circuit flux return associated with magnets 660.

Field lines in first magnetic field 650 are arranged to deflect particles in a yz-plane, while field lines in second magnetic field 655 are arranged to deflect particles in an xy-plane. Specifically, as a particle with velocity is deflected in a direction along a y-axis 608b by first magnetic field 650, second magnetic field 655 causes the particle to also deflect in the xy-plane. Hence, the particle is likely diverted into extension 618 or, more generally, a side of reticle shield 604.

In general, if second magnetic field 655 is significantly stronger in the plane of coil 680 in comparison to beneath coil 680 or above coil 680 relative to z-axis 608c, particles entering second magnetic field 655 at a relatively large angle with respect to z-axis 608c are often reflected by second magnetic field 655. Such particles will circulate more rapidly as they enter into stronger portions of second magnetic field 655. Hence, the kinetic energy of these particles in a direction along z-axis 608c decreases as their transverse kinetic energy, or kinetic energy in an xy-plane, increases. In some situations, the kinetic energy of these particles in a direction along z-axis 608c may decrease to the point where the kinetic energy in a direction along z-axis 608c is approximately zero, at which point the motion of the particles in a direction along z-axis 608c reverses. The reversal of the motion of the particles will prevent at least some of these particles from coming into contact with reticle 600. As will be understood by those skilled in the art, this behavior of a non-uniform magnetic field may be referred to as a magnetic mirror.

While the use of magnets 650 and coil 655 to create magnetic fields while enabling a distance between magnets 650 to remain relatively small is effective in reducing the maximum deflection for particles, an implementation which utilizes both magnets 650 and coil 655 may create a fringe field which may adversely affect various mechanisms included in an overall EUV lithography apparatus. As such, various shields (not shown) may be implemented in the overall EUV lithography apparatus to minimize the effect of fringe fields. Such shields may include, but are not limited to, shields which protect motors which move a reticle stage (not shown) which enable reticle 600 to scan from fringe fields or, more general, first magnetic field 650 and second magnetic field 655.

In another embodiment of FIGS. 6a, 6b, reticle shield 604 may be made of a high magnetic permeability material which shields the reticle 604 from the field lines of second magnetic field 655. Since charged particles traveling along magnetic field lines are not deflected, field lines which intercept the reticle represent an access to the reticle for charged particles. Such a shield may also protect parts of the reticle stage which are sensitive to magnetic fields.

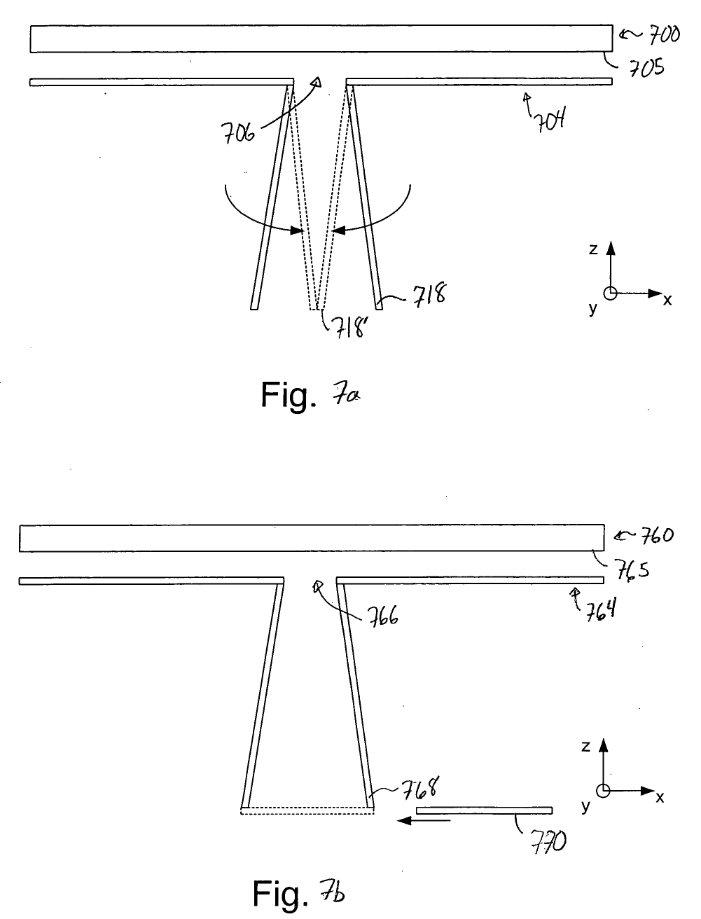

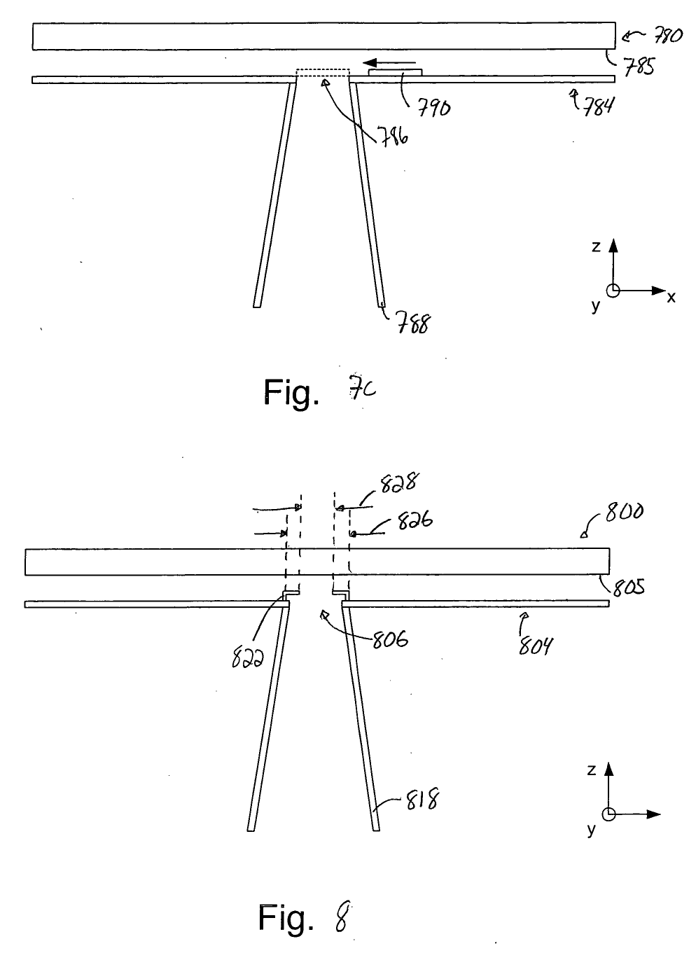

A cover for a reticle shield or, more specifically, a cover for the opening through which EUV beams may pass, may be desired in some instances to protect a reticle, for example, when EUV radiation is not present. That is, a cover for an opening in a reticle shield may prevent particles from contaminating a reticle when the reticle is not being subjected to EUV radiation. FIG. 7a is a diagrammatic cross-sectional side view representation of a cover for an opening in a reticle shield in accordance with an embodiment of the present invention. An extension 718 of a reticle shield 704 may be arranged to substantially collapse such that a cover 718′ for opening 706 is effectively formed. When extension 718 collapses to form cover 718′ , particles may be prevented from passing within extension 718 through an opening 706 defined within reticle shield 704 to a front surface 705 of a reticle 700.

Alternatively, a mechanism which allows an opening in a reticle shield to be covered may be a shutter which may be slid into place, flipped into place, or otherwise positioned over an end of extension. FIG. 7b is a diagrammatic cross-sectional side view representation of a shutter that effectively covers an opening in a reticle shield in accordance with an embodiment of the present invention. A shutter 770, which may be coupled to a reticle shield 764 or be a separate piece that is not a component of reticle shield 764, is arranged to cover an end of an extension 768 of reticle shield 764. Shutter 770, when positioned over extension 768, is effective in preventing particles from passing through an opening 766 in reticle shield 764 and onto a front surface 765 or a reticle 760. Shutter 770 may be retractable, i.e., shutter 770 may effectively cover opening 766 when deployed and may effectively leave opening 766 uncovered when in a retracted position.

In one embodiment, a shutter may be arranged to substantially directly cover an opening within a reticle shield, as shown in FIG. 7c. FIG. 7c is a diagrammatic cross-sectional side view representation of a shutter that directly covers an opening in a reticle shield in accordance with an embodiment of the present invention. A shutter 790 is arranged to be positioned at an opening 786 in a reticle shield 784 to prevent particles from entering an extension 788, passing through opening 786 and becoming attached to a front surface 785 of a reticle 780 when reticle 780 is not subjected to EUV radiation.

Depending upon the configuration of and the requirements of a particular EUV lithography system, it may be desirable to allow the limits of an illuminated region on a reticle to be adjustable. In other words, in some systems, the ability to vary the effective size of an opening in a reticle shield may allow the size of an illuminated region on a reticle to be altered. With reference to FIG. 8, a blind arrangement which allows the size of an opening to be effectively altered will be described in accordance with an embodiment of the present invention. The effective size of an opening 806 in a reticle shield 804 may be controlled by controlling the position of a blind 822. While opening 806 may enable an area 826 on a front surface 805 of a reticle 800 to be illuminated by EUV radiation (not shown), blind 822 may be used to allow a smaller area 828 on front surface 805 to be illuminated. Blind 822 may be adjustable such that area 828 may vary according to the requirements of a particular system.

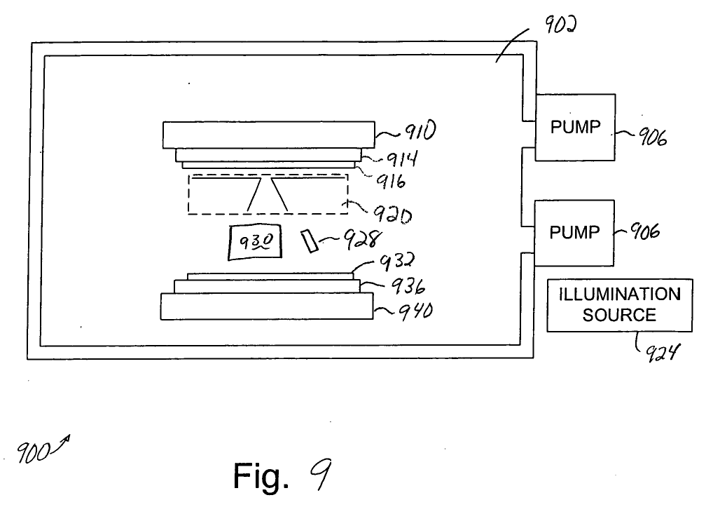

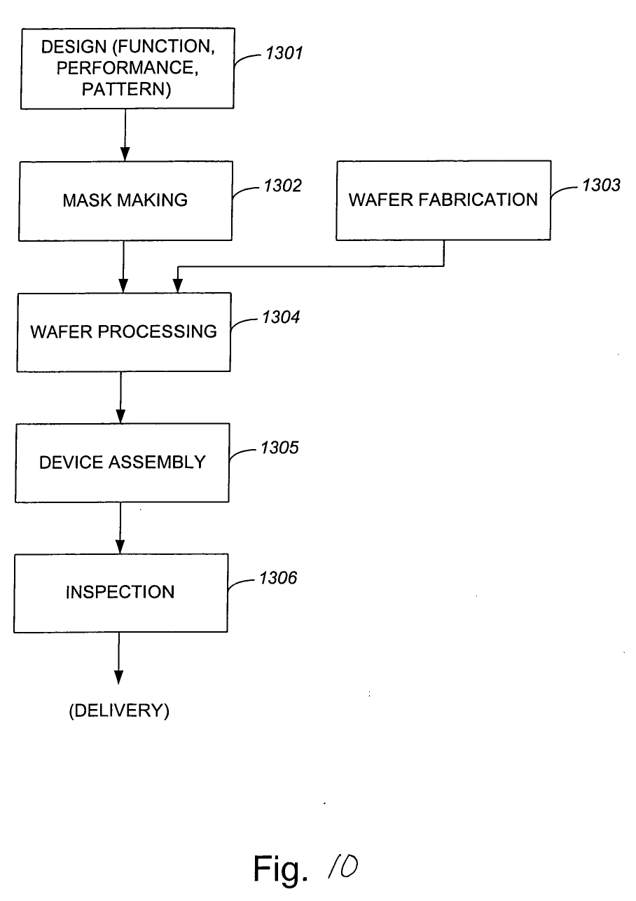

With reference to FIG. 9, a EUV lithography system will be described in accordance with an embodiment of the present invention. An EUV lithography system 900 includes a vacuum chamber 902 with pumps 906 which are arranged to enable a desired vacuum level to be maintained within vacuum chamber 902. Various components of EUV lithography system 900 are not shown, for ease of discussion, although it should be appreciated that EUV lithography system 900 may generally includes components such as a reaction frame, a vibration isolation mechanism, actuators, and controllers.

An EUV reticle 916, which may be held by a reticle chuck 914 coupled to a reticle stage assembly 910 that allows the reticle to scan, is positioned such that when an illumination source 924 provides beams which subsequently reflect off of a mirror 928, the beams reflect off of a front surface of reticle 916. A reticle shield assembly 920 is arranged to protect reticle 916 such that contamination of reticle 916 by particles may be reduced.

As discussed above, reticle shield assembly 920 may include an opening through which beams, e.g., EUV radiation, may illuminate a portion of reticle 916. Incident beams on reticle 916 may be reflected through a projection optics system onto a surface of a wafer 932 held by a wafer chuck 936 on a wafer stage assembly 940 which allows wafer 932 to scan. Hence, images on reticle 916 may be projected onto wafer 932.

Wafer stage assembly 940 may generally include a positioning stage that may be driven by a planar motor, as well as a wafer table that is magnetically coupled to the positioning stage by utilizing an EI-core actuator. Wafer chuck 936 is typically coupled to the wafer table of wafer stage assembly 940, which may be levitated by any number of voice coil motors. The planar motor which drives the positioning stage may use an electromagnetic force generated by magnets and corresponding armature coils arranged in two dimensions. The positioning stage is arranged to move in multiple degrees of freedom, e.g., between three to six degrees of freedom to allow wafer 932 to be positioned at a desired position and orientation relative to a projection optical system reticle 916.

Movement of the wafer stage assembly 940 and reticle stage assembly 910 generates reaction forces which may affect performance of an overall EUV lithography system 900. Reaction forces generated by the wafer (substrate) stage motion may be mechanically released to the floor or ground by use of a frame member as described above, as well as in U.S. Pat. No. 5,528,118 and published Japanese Patent Application Disclosure No. 8-166475. Additionally, reaction forces generated by motion of reticle stage assembly 910 may be mechanically released to the floor (ground) by use of a frame member as described in U.S. Pat. No. 5,874,820 and published Japanese Patent Application Disclosure No. 8-330224, which are each incorporated herein by reference in their entireties.

An EUV lithography system according to the above-described embodiments, e.g., a lithography apparatus which may include a reticle shield, may be built by assembling various subsystems in such a manner that prescribed mechanical accuracy, electrical accuracy, and optical accuracy are maintained. In order to maintain the various accuracies, prior to and following assembly, substantially every optical system may be adjusted to achieve its optical accuracy. Similarly, substantially every mechanical system and substantially every electrical system may be adjusted to achieve their respective desired mechanical and electrical accuracies. The process of assembling each subsystem into a photolithography system includes, but is not limited to, developing mechanical interfaces, electrical circuit wiring connections, and air pressure plumbing connections between each subsystem. There is also a process where each subsystem is assembled prior to assembling a photolithography system from the various subsystems. Once a photolithography system is assembled using the various subsystems, an overall adjustment is generally performed to ensure that substantially every desired accuracy is maintained within the overall photolithography system. Additionally, it may be desirable to manufacture an exposure system in a clean room where the temperature and humidity are controlled.

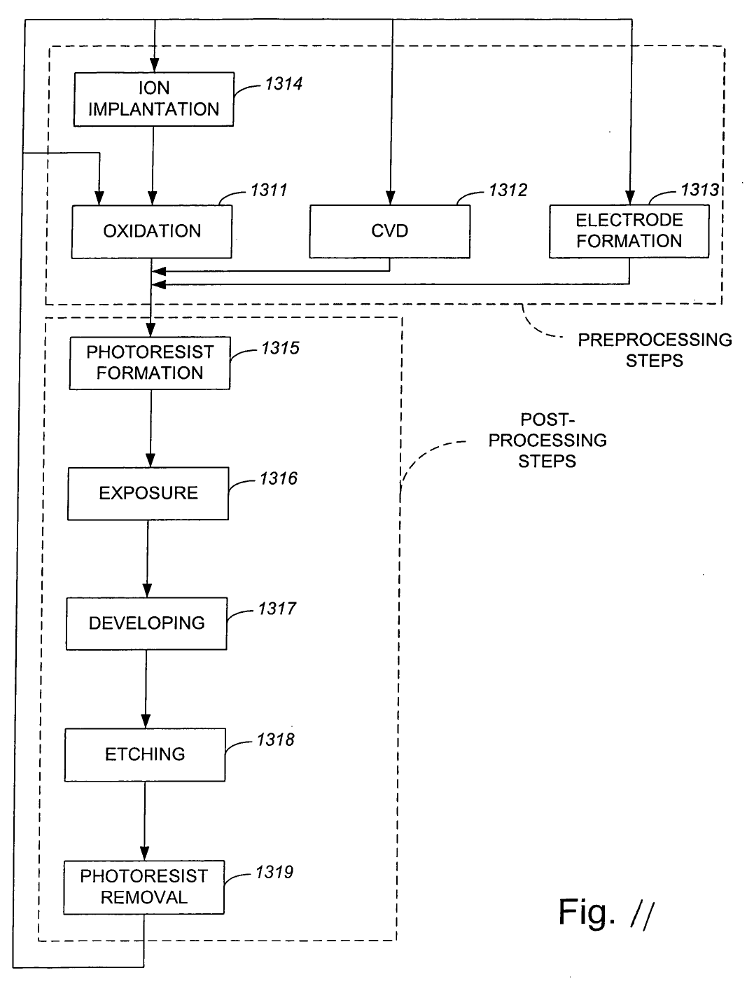

Further, semiconductor devices may be fabricated using systems described above, as will be discussed with reference to FIG. 10. The process begins at step 1301 in which the function and performance characteristics of a semiconductor device are designed or otherwise determined. Next, in step 1302, a reticle (mask) in which has a pattern is designed based upon the design of the semiconductor device. It should be appreciated that in a parallel step 1303, a wafer is made from a silicon material. The mask pattern designed in step 1302 is exposed onto the wafer fabricated in step 1303 in step 1304 by a photolithography system. One process of exposing a mask pattern onto a wafer will be described below with respect to FIG. 11. In step 1305, the semiconductor device is assembled. The assembly of the semiconductor device generally includes, but is not limited to, wafer dicing processes, bonding processes, and packaging processes. Finally, the completed device is inspected in step 1306.

FIG. 11 is a process flow diagram which illustrates the steps associated with wafer processing in the case of fabricating semiconductor devices in accordance with an embodiment of the present invention. In step 1311, the surface of a wafer is oxidized. Then, in step 1312 which is a chemical vapor deposition (CVD) step, an insulation film may be formed on the wafer surface. Once the insulation film is formed, in step 1313, electrodes are formed on the wafer by vapor deposition. Then, ions may be implanted in the wafer using substantially any suitable method in step 1314. As will be appreciated by those skilled in the art, steps 1311-1314 are generally considered to be preprocessing steps for wafers during wafer processing. Further, it should be understood that selections made in each step, e.g., the concentration of various chemicals to use in forming an insulation film in step 1312, may be made based upon processing requirements.

At each stage of wafer processing, when preprocessing steps have been completed, post-processing steps may be implemented. During post-processing, initially, in step 1315, photoresist is applied to a wafer. Then, in step 1316, an exposure device may be used to transfer the circuit pattern of a reticle to a wafer. Transferring the circuit pattern of the reticle of the wafer generally includes scanning a reticle scanning stage which may, in one embodiment, include a force damper to dampen vibrations.

After the circuit pattern on a reticle is transferred to a wafer, the exposed wafer is developed in step 1317. Once the exposed wafer is developed, parts other than residual photoresist, e.g., the exposed material surface, may be removed by etching. Finally, in step 1319, any unnecessary photoresist that remains after etching may be removed. As will be appreciated by those skilled in the art, multiple circuit patterns may be formed through the repetition of the preprocessing and post-processing steps.

Although only a few embodiments of the present invention have been described, it should be understood that the present invention may be embodied in many other specific forms without departing from the spirit or the scope of the present invention. By way of example, a shield which is used in conjunction with a magnetic field to protect a surface from particles has generally been described as a reticle shield. Such a shield, however, may instead be used to protect a surface of a wafer from particles. That is, a shield may be arranged to protect either a reticle or a wafer. Further, such a shield is not limited to being used in an EUV lithography system, and may be used in substantially any system within which reducing particle contamination is desired.

In general, the size and the shape of a reticle shield may vary widely. Additionally, the size and the shape of an opening in a reticle shield may also be widely varied. An appropriate size and an appropriate shape may be chosen based upon the characteristics of an overall system in which the reticle shield is used. When a reticle shield includes an extension, while the extension has been described as being substantially wedgelike in shape, the shape of the extension may vary. For example, an extension may have an approximately pyramidal shape.

A shutter has been described as being suitable for use in either indirectly covering an opening in a reticle shield by covering one end of an extension of the reticle shield, or by directly covering the opening. It should be appreciated that a shutter, or a cover in general, may be used to cover an opening in a reticle shield that does not include an extension. Further, the configuration of a cover may vary widely.

A static magnetic field has been described as being applied by permanent magnets. In lieu of using permanent magnets as pole pieces to generate a magnetic field, a magnetic field may instead be generated using electromagnets without departing from the spirit or the scope of the present invention. Therefore, the present examples are to be considered as illustrative and not restrictive, and the invention is not to be limited to the details given herein, but may be modified within the scope of the appended claims.

1. An apparatus, the apparatus being arranged to protect a surface of an object, the apparatus comprising:
a plate, the plate being arranged in proximity to the surface, the plate being arranged to protect at least a first portion of the surface;
an opening, the opening being defined within the plate, wherein the opening is arranged such that a second portion of the surface is exposed through the opening; and
at least one magnetic component, the at least one magnetic component being arranged to create a magnetic field that is arranged to deflect charged particles away from the opening and the surface of the object.

2. The apparatus of claim 1 further including:
an extension, the extension being coupled to the plate, the extension further being arranged about the opening.

3. The apparatus of claim 2 wherein the extension is relatively wedgelike in shape.

4. The apparatus of claim 2 wherein the at least one magnetic component includes a plurality of permanent magnetic pole pieces arranged about the extension.

5. The apparatus of claim 4 further including:
a flux return circuit, the flux return circuit being couple to the plurality of magnetic pole pieces to enable flux to flow between the plurality of magnetic pole pieces.

6. The apparatus of claim 4 further including:
an additional magnetic component, the additional magnetic component being arranged about the plurality of magnetic pole pieces, wherein the additional magnetic component is arranged to create an additional magnetic field that is arranged to further deflect the charged particles away from the opening and the surface of the object.

7. The apparatus of claim 6 wherein the magnetic field includes flux lines in a first plane and the additional magnetic field includes flux lines in a second plane.

8. The apparatus of claim 6 wherein the additional magnetic component is one of a coil and a permanent magnet.

9. The apparatus of claim 4 wherein the plurality of magnetic pole pieces are permanent magnets.

10. The apparatus of claim 1 further including:
a retractable cover, the cover being arranged to substantially cover the opening when the apparatus when in a deployed position, the cover further being arranged not to cover the opening when in a retracted position.

11. The apparatus of claim 1 further including:
a blind, the blind being substantially coupled to the plate about the opening, the blind being arranged to effectively alter a size of the second portion of the surface that is exposed through the opening.

12. The apparatus of claim 1 wherein the object is a reticle used in an extreme ultraviolet lithography system.

13. A lithographic system comprising:
an object holder, the object holder being arranged to support an object having a front surface that is to be protected from particles;
an illumination source, the illumination source being arranged to supply a beam, the beam being arranged to provide the particles with charges;
a shield, the shield being positioned in proximity to the object holder, the shield defining an opening through which the beam may pass to substantially illuminate an area of the object that is arranged to be supported by the object holder; and
a magnetic arrangement, the magnetic arrangement being arranged to provide a magnetic field to deflect the charged particles away from the opening defined in the shield, wherein the magnetic field and the shield cooperate to substantially protect the object arranged to be supported by the object holder from the charged particles.

14. The lithographic system of claim 13 wherein the beam is a beam of radiation.

15. The lithographic system of claim 13 wherein the magnetic arrangement includes a first magnetic pole, a second magnetic pole, and a flux return circuit arranged to create a first component of the magnetic field.

16. The lithographic system of claim 15 wherein the magnetic arrangement further includes a coil, the coil being arranged to create a second component of the magnetic field, the first component of the magnetic field and the second component of the magnetic field having magnetic field lines along different axes.

17. The lithographic system of claim 13 wherein the shield includes an extension, the extension being arranged to substantially surround edges of the opening and shaped to enable a profile of the beam to pass through the extension substantially without coming into contact with the sides of the extension.

18. The lithographic system of claim 13 wherein the shield includes a blind arrangement, the blind arrangement being arranged to substantially control a size of the illuminated area of the object arranged to be supported by the object holder.

19. The lithographic system of claim 13 wherein the object arranged to be supported by the object holder is a reticle.

20. A device manufactured with the lithographic system of claim 13.

21. A wafer on which an image has been formed using the lithographic system of claim 19.

22. A method for reducing particle contamination on a surface of an object, the method comprising:
providing a shield in proximity to the surface of the object, the shield having an opening defined therein;
providing a beam through the opening defined in the shield, the beam being arranged to substantially illuminate an area of the surface, wherein the beam is arranged to charge particles which pass through the beam;
creating a first magnetic field, the first magnetic field being arranged to substantially encompass the opening; and
deflecting the charged particles away from the opening and the surface of the object using the first magnetic field.

23. The method of claim 22 wherein the shield includes an extension, the extension being arranged substantially about the opening, and wherein providing the beam through the opening defined in the shield includes providing the beam through the extension.

24. The method of claim 22 further including:
creating a second magnetic field, the second magnetic field being arranged to substantially encompass the opening, the second magnetic field having magnetic field lines along a different axis than magnetic field lines of the first magnetic field; and
deflecting the charged particles away from the opening using the second magnetic field.

25. The method of claim 22 wherein the object is a reticle and the beam is a radiation beam.

26. The method of claim 25 wherein the reticle is arranged to be used with an extreme ultraviolet lithography process and the radiation beam is an extreme ultraviolet radiation beam.
